(19) United States
(12) Patent Application Publication
(10) Pub. No.: US 2026/0037040 A1
(43) Pub. Date: Feb. 5, 2026

(54) DISPLAY PANEL AND ELECTRONIC DEVICE

(71) Applicant: Wuhan China Star Optoelectronics Semiconductor Display Technology Co., Ltd., Wuhan, Hubei (CN)

(72) Inventors: Xinpeng SHAN, Wuhan, Hubei (CN); Chengjie JIA, Wuhan, Hubei (CN)

(73) Assignee: Wuhan China Star Optoelectronics Semiconductor Display Technology Co., Ltd., Wuhan, Hubei (CN)

(21) Appl. No.: 18/565,185

(22) PCT Filed: Jun. 28, 2023
(86) PCT No.: PCT/CN2023/103021

§ 371 Date: Nov. 29, 2023

(30) Foreign Application Priority Data
Dec. 13, 2022 (CN) 202211601336.4

(51) Int. Cl. G06F 1/16; H10K 77/10; H10K 102/00

(52) U.S. Cl. CPC G06F 1/1681; G06F 1/1652; H10K 77/111; H10K 2102/311

(57) ABSTRACT

The present application provides a display panel and an electronic device, the display panel includes at least three middle frames and at least two hinges, every two adjacent said middle frames being rotatably connected, each of said hinges being connected to two adjacent said middle frames, and torques of any two adjacent hinges are different. A hinge with a small torque is closed first, and a hinge with a large torque is closed later, so that the display panel can be folded according to a preset folding order, and the problem that the existing folding display device is vulnerable to being folded is solved.

### TECHNICAL FIELD

The present application relates to display technologies, and more particularly, to a display panel and an electronic device.

### BACKGROUND

With the development of display technology, large-screen display devices are becoming more and more popular in the market. However, as size of a screen increases, the inconvenience of carrying follows. In order to improve the convenience of carrying, various folding display devices have emerged. For a display device that needs to be folded multiple times, it is necessary to fold in a certain folding order. If folding is not performed in a certain folding order, the folding device is easily damaged.

### SUMMARY

The present application provides a display panel and an electronic device for alleviating a technical problem that an existing folding display device is vulnerable when folded.

To solve the above problems, the present application provides the following technical solutions:

One or more embodiments of the present application provides a display panel comprising:
at least three middle frames, every two adjacent said middle frames being rotatably connected; and
at least two hinges, each of said hinges connected to two adjacent said middle frames;
wherein torques of any two adjacent hinges are different.

In the display panel provided in the embodiment of the present application, when the display panel is in a first state, the at least three middle frames are successively arranged in a first direction to form a flat surface, wherein any three adjacent middle frames are successively a first middle frame, a second middle frame and a third middle frame, the second middle frame is positioned between the first middle frame and the third middle frame, the first middle frame is rotatably connected to the second middle frame through a first hinge, the third middle frame is rotatably connected to the second middle frame through a second hinge, and the torque of the first hinge is less than the torque of the second hinge; when the display panel is in a second state, the second middle frame, the first middle frame, and the third middle frame are arranged to overlap in a second direction, and the first middle frame is positioned between the second middle frame and the third middle frame.

In the display panel provided in the embodiment of the present application, in the first direction, a length of the first middle frame is smaller than a length of the second middle frame, and a length of the second middle frame is smaller than a length of the third middle frame.

In the display panel provided in the embodiment of the present application, when the display panel is in the first state, a thickness of the first middle frame gradually increases in the first direction, a thickness of the third middle frame gradually decreases in the first direction, and a thickness of a side of the first middle frame close to the first hinge is larger than a thickness of a side of the first middle frame away from the first hinge.

In the display panel provided in the embodiment of the present application, one of the first hinge and the second hinge is a flex hinge and the other is a U-shaped hinge.

In a display panel provided in the embodiment of the present application, the first hinge includes:
a first fixing bracket including a first body bracket;
a first supporting mechanism including a first support and a second support positioned at opposite sides of the first body bracket, the first support being rotatably connected to one side of the first body bracket and the second support being rotatably connected to the other side of the first body bracket;
a first rotating mechanism, including a first rotator, a second rotator, a first connector, and a second connector, one end of the first rotator being rotatably connected to one side of the first support away from the first body bracket, the other side of the first rotator being fixedly connected to the first middle frame, one end of the second rotator being rotatably connected to one side of the second support away from the first body bracket, the other side of the second rotator being fixedly connected to the second middle frame, one end of the first connector being slidably connected to the first rotator, and one end of the second connector being slidably connected to the second rotator;
a first linkage mechanism, wherein the other end of the first connector is fixedly connected to one end of the first linkage mechanism, and the other end of the second connector is fixedly connected to the other end of the first linkage mechanism so that the first rotator and the second rotator rotate synchronously.

In the display panel provided in the embodiment of the present invention, the first rotating mechanism further includes a first rotating shaft and a second rotating shaft, the first rotating shaft being fixedly connected to the first connector and fixedly connected to the end of the first linkage mechanism; the second rotating shaft being fixedly connected to the second connector and fixedly connected to the other end of the first linkage mechanism.

In the display panel provided in the embodiment of the present application, the first fixing bracket further includes a first bracket and a second bracket, the first bracket being positioned between the second bracket and the first body bracket, the first linkage mechanism being provided between the first bracket and the first body bracket, wherein the first rotating shaft and the second rotating shaft are rotatably connected to the first body bracket, and the first bracket and the second bracket are sleeved on the first rotating shaft and the second rotating shaft.

In the display panel provided in the embodiment of the present application, the first linkage mechanism includes a first linkage connected to the first rotating shaft, a second linkage connected to the second rotating shaft, and a third linkage, the first linkage being synchronously connected to the second linkage through the third linkage to synchronously rotate the first rotating shaft and the second rotating shaft.

In the display panel provided in the embodiment of the present invention, the other end of the other end of the first connector is provided with a first cam on a side away from the first linkage, and the other end of the second connector is provided with a second cam on a side away from the second linkage;
the first hinge further includes a first positioning mechanism, wherein the first positioning mechanism comprises a first positioner sleeved on the first rotating shaft and the second rotating shaft, a first concave wheel matched with the first cam is arranged on one side of the first positioner close to the first connector, and a second concave wheel matched with the second cam is arranged on one side of the first positioner close to the second connector.

In the display panel provided in the embodiment of the present application, the first positioning mechanism further comprises a first elastic element and a second elastic element, wherein the first elastic element is sleeved on the first rotating shaft, the second elastic element is sleeved on the second rotating shaft, both the first elastic element and the second elastic element are positioned between the first positioner and the second bracket, and both the first elastic element and the second elastic element are in an elastically deformed state.

In a display panel provided in one or more embodiments of the present application, the second hinge includes:
a second fixing bracket, comprising a second body bracket;
a second supporting mechanism, comprising a third support and a fourth support positioned on opposite sides of the second body bracket, wherein the third support being rotatably connected to one side of the second body bracket, one side of the third support away from the second body bracket being fixedly connected to the second middle frame, and the fourth support being rotatably connected to the other side of the second body bracket, and one side of the fourth support away from the second body bracket being fixedly connected to the third middle frame;
a second rotating mechanism, comprising a third rotator slidably connected to the third support and a fourth rotator slidably connected to the fourth support;
a second linkage mechanism, through which the third rotator is connected to the fourth rotator so that the third rotator and the fourth rotator rotate synchronously.

In the display panel provided in the embodiment of the present invention, the second fixing bracket further includes a third bracket and a fourth bracket, the third bracket is positioned between the fourth bracket and the second body bracket, and the second linkage mechanism is disposed between the third bracket and the fourth bracket;
the second linkage mechanism includes a fourth linkage, a fifth linkage and a sixth linkage, wherein the fourth linkage is fixedly connected to the third rotator, the sixth linkage is fixedly connected to the fourth rotator, the fifth linkage is rotatably connected to the third bracket, and the fourth linkage is synchronously connected to the sixth linkage by the fifth linkage so that the third rotator and the fourth rotator rotate synchronously.

In the display panel provided in the embodiment of the present invention, the second rotating mechanism further comprises a third rotating shaft rotatably connected to the third bracket and the fourth bracket, and a fourth rotating shaft rotatably connected to the third bracket and the fourth bracket;
the third rotator is provided with a third cam on one side close to the third bracket, the third cam is sleeved on the third rotating shaft, the fourth rotator is provided with a fourth cam on one side close to the third bracket, and the fourth cam is sleeved on the fourth rotating shaft;
the second hinge further comprises a second positioning mechanism, wherein the second positioning mechanism comprises a second positioner, a third elastic element and a fourth elastic element, the second positioner is sleeved on the third rotating shaft and the fourth rotating shaft, a third concave wheel matched with the third cam is arranged on one side of the second positioner close to the third rotator, and a fourth concave wheel matched with the fourth cam is arranged on one side of the second positioner close to the fourth rotator;
the third elastic element is sleeved on the third rotating shaft, the fourth elastic element is sleeved on the fourth rotating shaft, both the third elastic element and the fourth elastic element are positioned between the second positioner and the fourth bracket, and both the third elastic element and the fourth elastic element are in an elastically deformed state.

In the display panel provided in the embodiment of the present application, the fourth linkage is integrally provided with the third cam, and the sixth linkage is integrally provided with the fourth cam.

In the display panel provided in the embodiment of the present invention, the third rotator is provided with a fifth cam on a side close to the fourth bracket, the fifth cam is sleeved on the third rotating shaft, the third elastic element is positioned between the second positioner and the fifth cam, and the fourth rotator is provided with a sixth cam on a side close to the fourth bracket, the sixth cam is sleeved on the fourth rotating shaft, and the fourth elastic element is positioned between the second positioner and the sixth cam;
the second positioning mechanism further comprises a third positioner, a fifth elastic element and a sixth elastic element, wherein the third positioner is sleeved on the third rotating shaft and the fourth rotating shaft, a fifth concave wheel matched with the fifth cam is arranged on one side of the third positioner close to the third rotator, and a sixth concave wheel matched with the sixth cam is arranged on one side of the third positioner close to the fourth rotator;
the fifth elastic element is sleeved on the third rotating shaft, the sixth elastic element is sleeved on the fourth rotating shaft, both the fifth elastic element and the sixth elastic element are positioned between the third positioner and the fourth bracket, and both the fifth elastic element and the sixth elastic element are in an elastically deformed state.

One or more embodiments of the present application further provides an electronic device including a display panel of one of the foregoing embodiments.

### BENEFICIAL EFFECT

In the display panel and the electronic device provided in the present application, the display panel including at least three middle frames and at least two hinges, each of the two adjacent middle frames being rotationally connected, each of the hinges being connected to the two adjacent middle frames, and torque of any two adjacent hinges being different. According to the present application, torque of the two adjacent hinges of the display panel is different. When a display panel is folded, a hinge with a small torque is closed first, and a hinge with a large torque is closed later, so that the display panel can be folded according to a preset folding order, damage to the display panel caused by not folding according to the folding order is avoided. In this way, fool-proofing is realized when the display panel being folded, and the problem that the existing folding display device is vulnerable to be folded is solved.

### DESCRIPTION OF THE DRAWINGS

In order that the embodiments or the technical solutions in the prior art may be described more clearly, reference will now be made to the accompanying drawings which are to be used in the description of the embodiments or the prior art, and it will be apparent that the accompanying drawings in the description are merely embodiments of the invention, and that other drawings may be made to those skilled in the art without involving any inventive effort.

FIG. 1 is a schematic top view of a display panel according to one or more embodiments of the present application.

FIG. 2 is a structure of the display panel of FIG. 1 with the flexible display panel body removed.

FIG. 3 is an exploded schematic view of the display panel of FIG. 1.

FIG. 4 is a schematic sectional view showing a display panel in a first state according to one or more embodiments of the present application.

FIG. 5 is a schematic sectional view showing a display panel in a second state according to one or more embodiments of the present application.

FIG. 6 is a diagram showing an overall structure of a first hinge according to one or more embodiments of the present application.

FIG. 7 is a diagram showing detailed structure of a first hinge body of FIG. 6.

FIG. 8 is an exploded view of the first hinge body of FIG. 7.

FIG. 9 is a diagram showing detailed structure of a first body bracket of FIG. 8.

FIG. 10 is a diagram showing detailed structure of a first rotator of FIG. 9.

FIG. 11 is a diagram showing an overall structure of a second hinge according to one or more embodiments of the present application.

FIG. 12 is a diagram showing detailed structure of a second hinge body of FIG. 11.

FIG. 13 is an exploded view of the second hinge body of FIG. 12.

FIG. 14 is a diagram showing detailed structure of a second body bracket of FIG. 13.

FIG. 15 is a diagram showing detailed structure of a third support of FIG. 13.

FIG. 16 is a diagram showing detailed structure of a third rotator of FIG. 13.

FIG. 17 is a torque simulation graph of a first hinge according to one or more embodiments of the present application.

FIG. 18 is a torque simulation graph of a second hinge according to one or more embodiments of the present application.

### EMBODIMENTS OF THE INVENTION

The following description of the embodiments is made with reference to the accompanying drawings to illustrate specific embodiments in which the present application may be implemented. The direction terms mentioned in the present application, such as [upper], [lower], [front], [rear], [left], [right], [inner], [outer], [side], and the like, are only directions with reference to the additional drawings. Thus, directional language is used to illustrate and understand the present application, and not to limit the present application. In the drawings, structurally similar elements are denoted by the same reference numerals. In the drawings, the thickness of some layers and regions is exaggerated for clarity of understanding and ease of description. That is, the dimensions and thickness of each component shown in the drawings are arbitrarily shown, but the present application is not limited thereto.

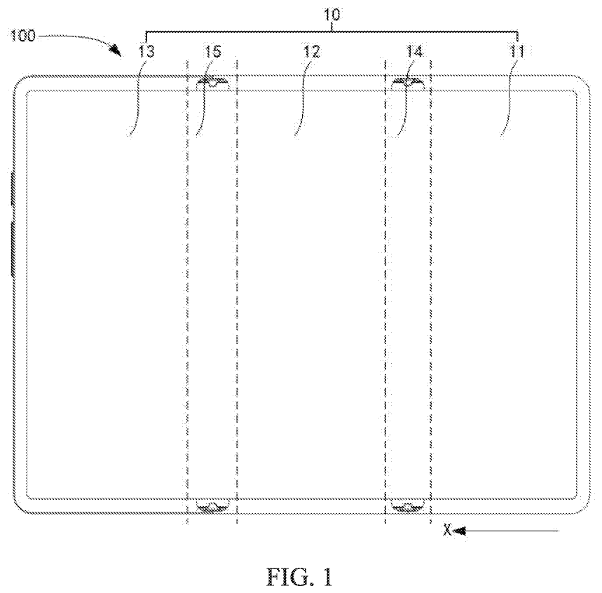

Referring to FIGS. 1 to 16, the present application provides a foldable display panel 100 including a flexible display panel body 10, a middle frame structure 20, and a hinge structure 30. The body of the flexible display panel 100 is attached to the middle frame structure 20. The middle frame structure 20 including at least three middle frames, and every two adjacent middle frames are rotatably connected. The hinge structure 30 includes at least two hinges, each of which is connected to two adjacent middle frames. In this case, torques of any two adjacent hinges are different. Therefore, when folding the display panel 100, the hinge having a relatively small torque will be closed first, and the hinge having a relatively large torque closed later, and the display panel 100 can be folded in a preset folding order, so that the display panel 100 is prevented from being damaged if the display panel 100 were not folded in the folding order. It is possible to realize a fool-proof folding of the display panel 100, and solve the problem that the existing folding display device is easily damaged when being folded.

In the following, a detailed description will be given on how the torques of two adjacent hinges are different.

When the display panel 100 is in a first state, the at least three middle frames are successively arranged in a first direction X, and a flat surface is formed to support and fix the body of the flexible display panel 100. The three adjacent middle frames are successively a first middle frame 21, a second middle frame 22 and a third middle frame 23. The second middle frame 22 is positioned between the first middle frame 21 and the third middle frame 23. The first middle frame 21 is rotatably connected to the second middle frame 22 through a first hinge 31. The third middle frame 23 is rotatably connected to the second middle frame 22 through a second hinge 32. The torque of the first hinge 31 is less than the torque of the second hinge 32.

When the display panel 100 is in a second state, the second middle frame 22, the first middle frame 21, and the third middle frame 23 are arranged to overlap in a second direction Y. And the first middle frame 21 is positioned between the second middle frame 22 and the third middle frame 23, so that the display panel 100 is in a folded configuration. In this way, an area of the display panel 100 is reduced, the portability is improved, and the portability inconvenience of the existing large-screen display device is solved. In this case the first direction X is a horizontal direction and the second direction Y is a vertical direction. Optionally, the first state is a flattened state and the second state is a bent state. When the display panel 100 is in a flattened state, a large-screen display of the display panel 100 is realized. When the display panel 100 is in a bent state, a partial display or folding function of the display panel 100 is realized.

In the following, the structure of the display panel 100 will be explained in detail by taking the middle frames including the three middle frames as an example.

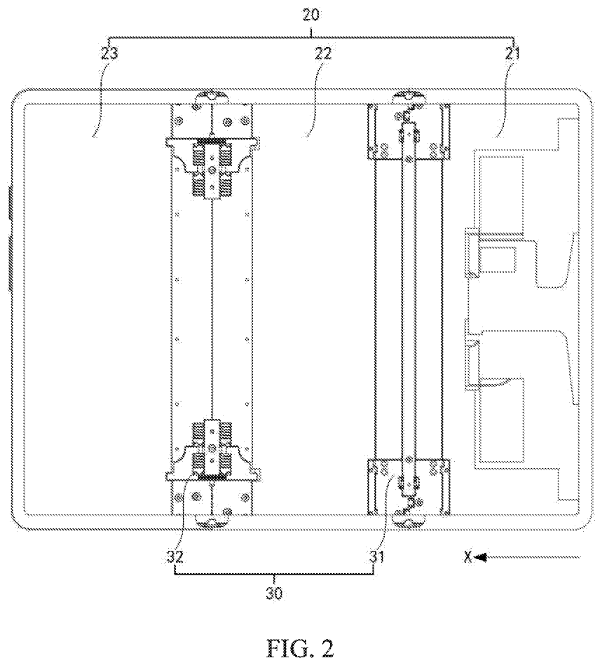

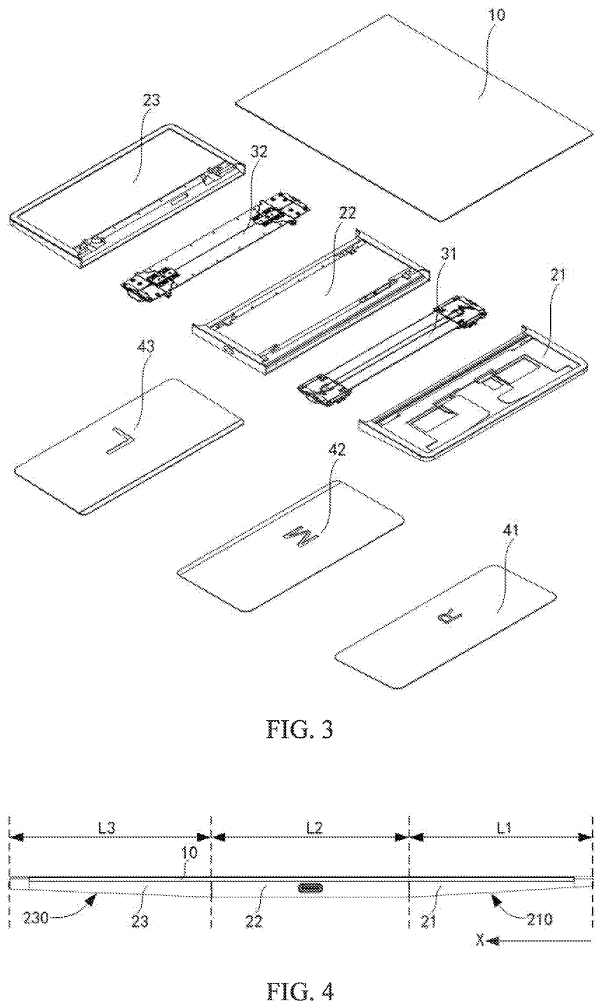

Referring to FIGS. 1 to 3, FIG. 1 is a schematic top view of a display panel according to one or more embodiments of the present application. FIG. 2 is a structure of the display panel of FIG. 1 with the flexible display panel body removed. FIG. 3 is an exploded schematic view of the display panel of FIG. 1. The flexible display panel body 10 includes a first portion 11, a second portion 12, a third portion 13, a first flexible portion 14 connected to the first portion 11 and the second portion 12, and a second flexible portion 15 connected to the second portion 12 and the third portion 13, as shown in FIG. 1. The first portion 11, the first flexible portion 14, the second portion 12, the second flexible portion 15, and the third portion 13 are consecutively arranged in the first direction X. The flexible display panel body 10 includes a bendable and foldable screen such as a flexible OLED display screen. And when the flexible display panel body 10 is a flexible OLED display screen, the flexible display panel 100 includes film layers such as a driving circuit layer, a light emitting function layer and a packaging layer in a stack arrangement.

The flexible display panel body 10 is attached to the middle frame structure 20, which includes the first middle frame 21, the second middle frame 22, and the third middle frame 23 arranged in sequence in the first direction X. The hinge structure 30 includes the first hinge 31 connected to the first middle frame 21 and the second middle frame 22 and the second hinge 32 connected to the second middle frame 22 and the third middle frame 23, as shown in FIG. 2. In this case, the first middle frame 21 corresponds to the first portion 11 of the flexible display panel body 10, the second middle frame 22 corresponds to the second portion 12, the third middle frame 23 corresponds to the third portion 13, the first hinge 31 corresponds to the first flexible portion 14, and the second hinge 32 corresponds to the second flexible portion 15.

Optionally, referring to FIG. 3, the display panel 100 further includes a rear cover provided on a side of the middle frame structure 20 facing away from the flexible display panel body 10. The rear cover includes a first rear cover 41 detachably connected to the first middle frame 21, a second rear cover 42 detachably connected to the second middle frame 22, and a third rear cover 43 detachably connected to the third middle frame 23.

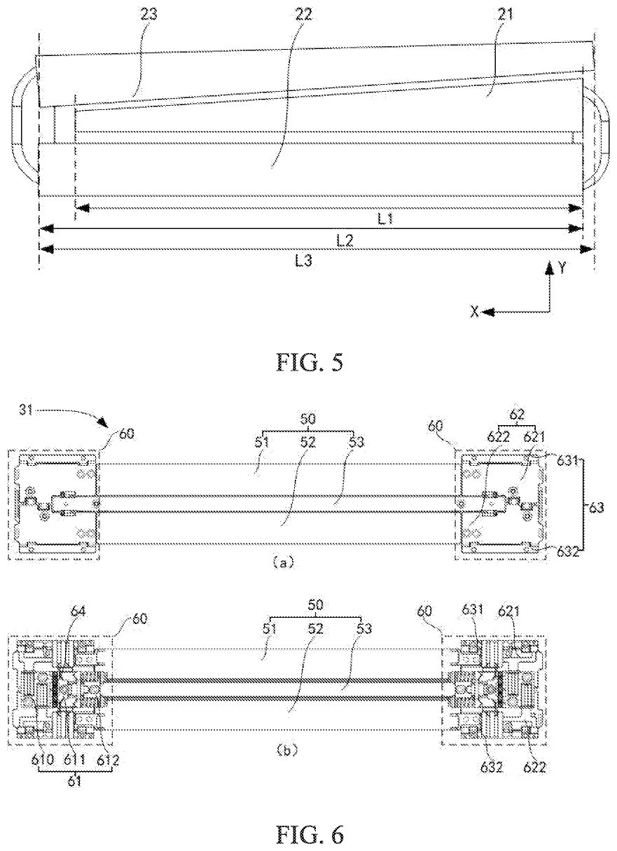

Referring to FIGS. 4 and 5, FIG. 4 is a schematic sectional view showing a display panel in a first state according to one or more embodiments of the present application. FIG. 5 is a schematic sectional view showing a display panel in a second state according to one or more embodiments of the present application. When the display panel 100 is in the first state, the first middle frame 21, the second middle frame 22, and the third middle frame 23 are arranged in the first direction X to form a flat surface to support and fix the flexible display panel body 10, and to allow the flexible display panel body 10 to be in the flattened state. When the display panel 100 is in the second state, the second middle frame 22, the first middle frame 21, and the third middle frame 23 are overlapped in the second direction Y, and the first middle frame 21 is positioned between the second middle frame 22 and the third middle frame 23. That is, when the display panel 100 changes from the first state to the second state, the first middle frame 21 is rotated with respect to the second middle frame 22, so that the first flexible portion 14 of the display panel 100 is bent, and the first portion 11 faces the second portion 12; the third middle frame 23 is rotated with respect to the second middle frame 22 so that the second flexible portion 15 of the display panel 100 is bent, and the third portion 13 faces the side of the first middle frame 21 facing away from the first portion 11. In this way, when the display panel 100 is in the second state, the first portion 11 is positioned between the second portion 12 and the third portion 13, so that the display panel 100 is formed to be a three-layer stacked structure in a “G”-shaped three-fold configuration, thereby reducing the area of the display panel 100 and improving the convenience of carrying it.

Optionally, in the first direction X, a length L1 of the first middle frame 21 is smaller than a length L2 of the second middle frame 22 to avoid interference between the first middle frame 21 and the second hinge 32. The length L2 of the second middle frame 22 is smaller than a length L3 of the third middle frame 23, so that an outer boundary of the third middle frame 23 in the folded display panel 100 is flush with an outer boundary of the display panel 100 as far as possible, thereby ensuring an aesthetic appearance of the folded display panel 100.

Optionally, when the display panel 100 is in the first state, the thickness of the first middle frame 21 gradually increases along the first direction X. The thickness of the third middle frame 23 gradually decreases along the first direction X. And the thickness of the first middle frame 21 on the side of the first middle frame 21 close to the first hinge 31 is greater than the thickness of the first middle frame 21 on the side of the first middle frame 21 away from the first hinge 31. Specifically, the first middle frame 21 is formed with a first inclined surface 210 on the side facing away from the flexible display panel body 10, and the third middle frame 23 is formed with a second inclined surface 230 on the side facing away from the flexible display panel body 10. When the display panel 100 is in the second state, due to the presence of the first inclined surface 210 and the second inclined surface 230, the relatively thick portion of the first middle frame 21 faces the relatively thin portion of the third middle frame 23, and the relatively thick portion of the first middle frame 21 faces a relatively thin portion of the third middle frame 23, so that an overall thickness of the folded display panel 100 can be reduced.

In one embodiment, one of the first hinge 31 and the second hinge 32 is a flex hinge and the other is a U-shaped hinge, where the flex hinge means that a bent configuration of the closed hinge is drop-shaped. U-shaped hinge means that a bent configuration of the closed hinge is U-shaped. However, the present application is not limited thereto, and the first hinge 31 and the second hinge 31 may be hinges of the same type, such as flex hinges or U-shaped hinges. The embodiments of the present application take the first hinge 31 as a flex hinge and the second hinge 32 as a U-shaped hinge as an example.

Further, the torque of the first hinge 31 is smaller than the torque of the second hinge 32, so that when identical external forces are applied to the display panel 100 to make it change from the first state to the second state, the first hinge 31 closes first because the torque is relatively small, and the second hinge 32 closes later because the torque is relatively large. In this way, the display panel 100 can be folded in a preset folding order, thereby avoiding damage to the display panel 100 if it were not folded in the folding order.

The structures of the first hinge 31 and the second hinge 32 will be explained in detail as follows.

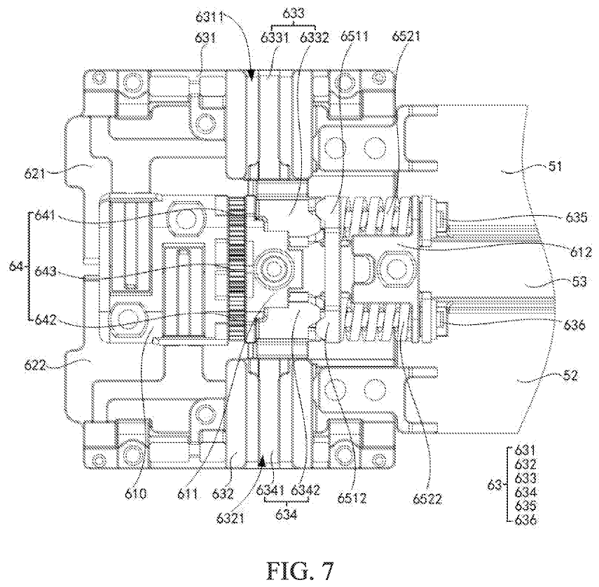

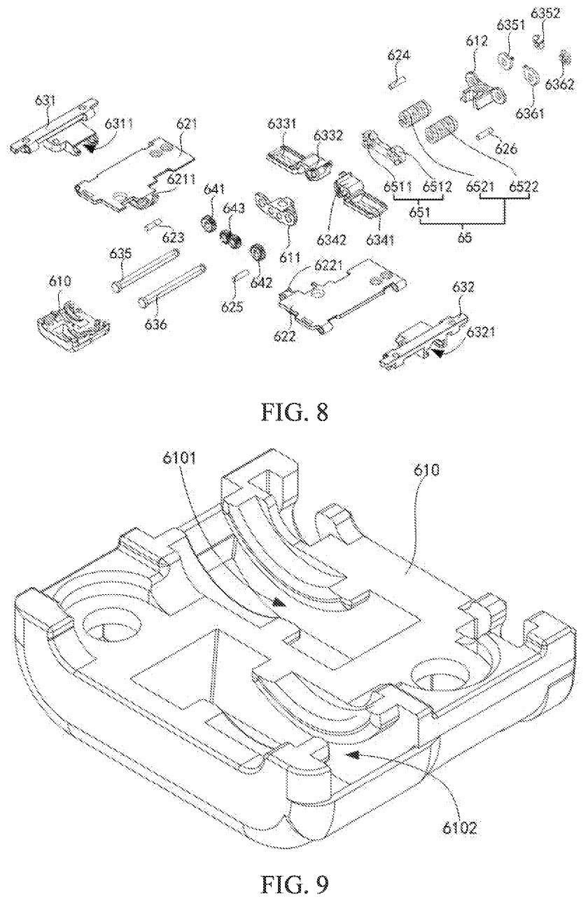

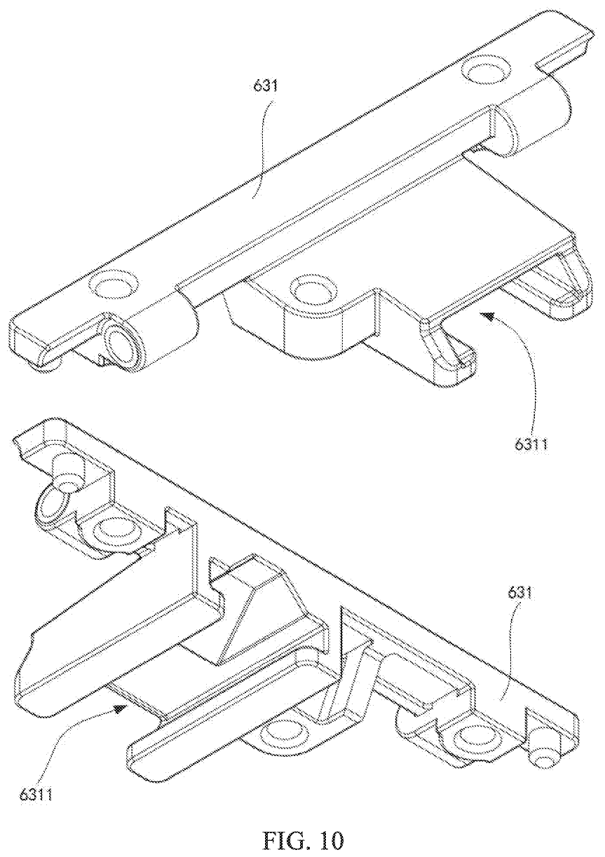

Referring to FIGS. 6 to 10, FIG. 6 is a diagram showing an overall structure of a first hinge according to one or more embodiments of the present application. FIG. 7 is a diagram showing detailed structure of a first hinge body in FIG. 6. FIG. 8 is an exploded view of the first hinge body in FIG. 7. FIG. 9 is a diagram showing detailed structure of a first body bracket in FIG. 8. FIG. 10 is a diagram showing detailed structure of a first rotator in FIG. 9. The first hinge 31 includes a first support plate 50 and two first hinge bodies 60 positioned on opposite sides of the first support plate 50. The first support plate 50 includes a first sub-supporting plate 51, a second sub-supporting plate 52, and a first lifting plate 53 positioned between the first sub-supporting plate 51 and the second sub-supporting plate 52, as shown in FIG. 6, where (a) in FIG. 6 is a schematic diagram showing structure of a front face of the first hinge 31, and (b) in FIG. 6 is a schematic diagram showing structure of a rear face of the first hinge 31. The front face of the first hinge 31 refers to the face of the first hinge 31 close to the flexible display panel body 10, and the rear face of the first hinge 31 refers to the face of the first hinge 31 away from the flexible display panel body 10. The first hinge body 60 includes a first fixing bracket 61, a first supporting mechanism 62, a first rotating mechanism 63, a first linkage mechanism 64, and a first positioning mechanism 65.

Referring to FIG. 7, the first fixing bracket 61 includes a first body bracket 610, a first bracket 611 and a second bracket 612, where the first bracket 611 is positioned between the first body bracket 610 and the second bracket 612, and the second bracket 612 is fixedly connected to the first lifting plate 53. The first supporting mechanism 62 includes a first support 621 and a second support 622 positioned on opposite sides of the first body bracket 610. The first support 621 rotatably connected to one side of the first body bracket 610 and fixedly connected to the first sub-supporting plate 51. The second support 622 rotatably connected to the other side of the first body bracket 610 and fixedly connected to the second sub-supporting plate 52.

Specifically, the first support 621 is provided with a first arc-shaped arm 6211 close to one side of the first body bracket 610, and the first body bracket 610 is provided with a first arc-shaped recess 6101 on the one side. The first arc-shaped arm 6211 is received in the first arc-shaped recess 6101 and slides in the first arc-shaped recess 6101. The second support 622 is provided with a second arc-shaped arm 6221 close to the other side of the first body bracket 610, and a second arc-shaped recess 6102 is provided on the other side of the first body bracket 610. The second arc-shaped arm 6221 is received in the second arc-shaped recess 6102 and slides in the second arc-shaped recess 6102. Specifically, the first body bracket 610 further includes at least a first limit and at least a second limit constituting the first arc-shaped recess 6101. The first limit includes a first arc-shaped surface and the second limit includes a second arc-shaped surface. The first arc-shaped surface and the second arc-shaped surface both face the first arc-shaped arm 6211 to limit the first arc-shaped arm 6211 within the first arc-shaped recess 6101.

The first rotating mechanism 63 includes a first rotator 631, a second rotator 632, a first connector 633, and a second connector 634. One end of the first rotator 631 is rotatably connected to one side of the first support 621 away from the first body bracket 610. The other side of the first rotator 631 is fixedly connected to the first middle frame 21. One end of the second rotator 632 is rotatably connected to one side of the second support 622 away from the first body bracket 610. The other side of the second rotator 632 is fixedly connected to the second middle frame 22. One end of the first connector 633 is slidably connected to the first rotator 631, and one end of the second connector 634 is slidably connected to the second rotator 632.

Optionally, the first rotator 631 and the first support 621 are rotatably connected by a first shaft 623 and a second shaft 624 and are each provided with a shaft hole. The first shaft 623 and the second shaft 624 pass through the shaft hole of the first rotator 631 and the shaft hole of the first support 621 so that the first rotator 631 and the first support 621 are rotatably connected. The second rotator 632 and the second support 622 are rotatably connected by a third shaft 625 and a fourth shaft 626, the second rotator 632 and the second support 622 are each provided with a shaft hole, and the third shaft 625 and the fourth shaft 626 pass through the shaft hole of the second rotator 632 and the shaft hole of the second support 622, so that the second rotator 632 and the second support 622 are rotatably connected.

Optionally, the one end of the first connector 633 is provided with a first lug 6331. The first rotator 631 is provided with a first sliding recess 6311 on the side close to the first support 621. The first lug 6331 is received in the first sliding recess 6311 and slides in the first sliding recess 6311. Specifically, one side of the first rotator 631 close to the first support 621 includes a protruding block positioned below the first support 621. The protruding block is provided with the first sliding recess 6311. The one end of the second connector 634 is provided with a second lug 6341. The second rotator 632 is provided with a second sliding recess 6321 on the side close to the second support 622. The second lug 6341 is received in the second sliding recess 6321 and slides in the second sliding recess 6321. Specifically, one side of the second rotator 632 close to the second support 622 also includes a protruding block positioned below the second support 622. The protruding block have the second sliding recess 6321 formed thereon.

The first linkage mechanism 64 is disposed between the first support 611 and the first body bracket 610. The other end of the first connector 633 is fixedly connected to one end of the first linkage mechanism 64. The other end of the second connector 634 is fixedly connected to the other end of the first linkage mechanism 64 so that the first rotator 631 and the second rotator 632 rotate synchronously.

The first rotating mechanism 63 further includes a first rotating shaft 635 and a second rotating shaft 636. The first rotating shaft 635 is fixedly connected to the first connector 633 and is fixedly connected to the end of the first linkage mechanism 64. The second rotating shaft 636 is fixedly connected to the second connector 634 and is fixedly connected to the other end of the first linkage mechanism 64. The first rotating shaft 635 and the second rotating shaft 636 are rotatably connected to the first body bracket 610. The first bracket 611 and the second bracket 612 are sleeved on the first rotating shaft 635 and the second rotating shaft 636. To prevent the second bracket 612 from falling off the first rotating shaft 635 and the second rotating shaft 636, the first hinge body 60 further includes a first fastener 6351 and a second fastener 6352 detachably connected to the first rotating shaft 635, and a third fastener 6361 and a fourth fastener 6362 detachably connected to the second rotating shaft 636.

The first linkage mechanism 64 includes a first linkage 641 connected to the first rotating shaft 635, a second linkage 642 connected to the second rotating shaft 636, and a third linkage 643. The first linkage 641 is synchronously connected to the second linkage 642 through the third linkage 643 to synchronously rotate the first rotating shaft 635 and the second rotating shaft 636.

The other end of the first connector 633 is provided with a first cam 6332 on a side away from the first linkage 641. And the other end of the second connector 634 is provided with a second cam 6342 on a side away from the second linkage 642. The first hinge 31 further includes a first positioning mechanism 65 including a first positioner 651 sleeved on the first rotating shaft 635 and the second rotating shaft 636. A first concave wheel 6511 matched with the first cam 6332 is provided on one side of the first positioner 651 close to the first connector 633. A second concave wheel 6512 matched with the second cam 6342 is provided on one side of the first positioner 651 close to the second connector 634.

The first positioning mechanism 65 further includes a first elastic element 6521 and a second elastic element 6522, where the first elastic element 6521 is sleeved on the first rotating shaft 635, and the second elastic element 6522 is sleeved on the second rotating shaft 636. The first elastic element 6521 and the second elastic element 6522 are both positioned between the first positioner 651 and the second bracket 612. The first elastic element 6521 and the second elastic element 6522 are both in an elastically deformed state.

Specifically, the first linkage 641 includes a first gear, the second linkage 642 includes a second gear, and the third linkage 643 includes two third gears meshing with each other. The two third gears are rotatably connected to the first body bracket 610 and the first bracket 611, the first gear is sleeved on the first rotating shaft 635, and the second gear is sleeved on the second rotating shaft 636. The first gear meshes with one of the two third gears, and the second gear meshes with the other of the two third gears.

Specifically, the first gear is provided with a positioning hole through which the first rotating shaft 635 passes, and the first rotating shaft 635 is in interference fit with the positioning hole of the first gear so that rotation of the first rotating shaft 635 can drive rotation of the first gear. Similarly, the second gear is provided with a positioning hole through which the second rotating shaft 636 passes, and the second rotating shaft 636 is in interference fit with the positioning hole of the second gear so that rotation of the second rotating shaft 636 can drive rotation of the second gear or the rotation of the second gear drive the rotation of the second rotating shaft 636. A rotation axis of the first connector 633, a rotation axis of the first gear, and a rotation axis of the first rotating shaft 635 coincide. A rotation axis of the second connector 634, a rotation axis of the second gear, and a rotation axis of the second rotating shaft 636 coincide.

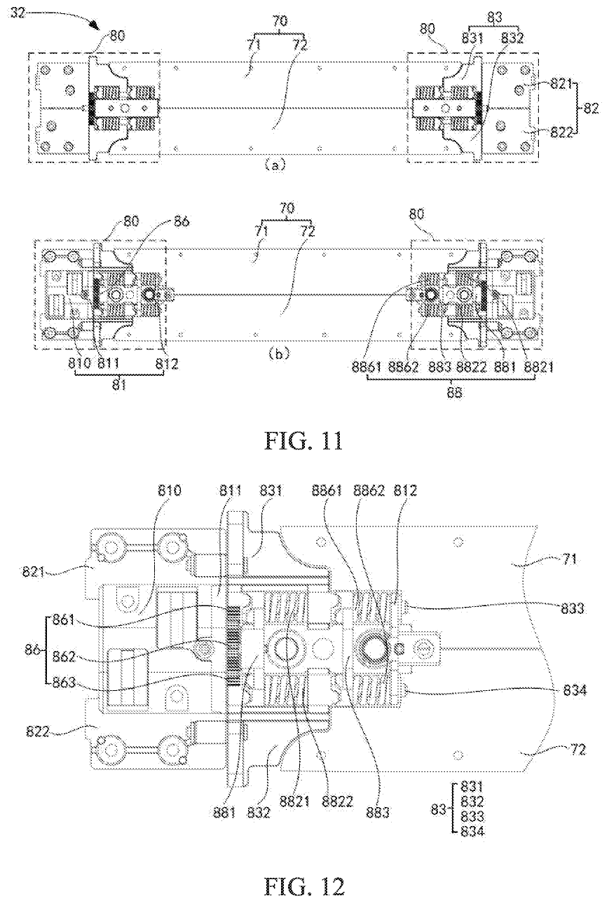

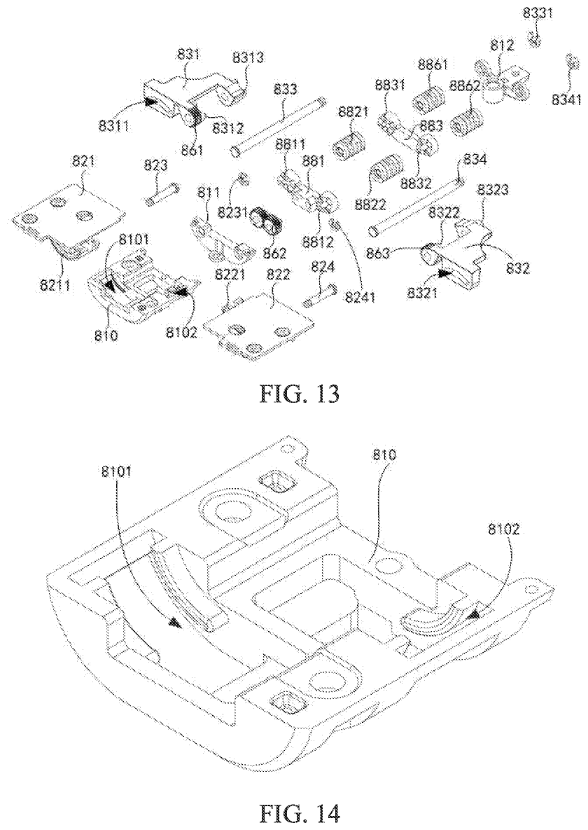

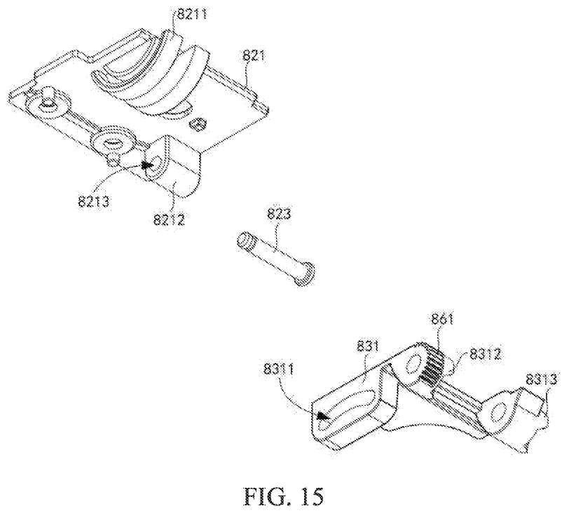

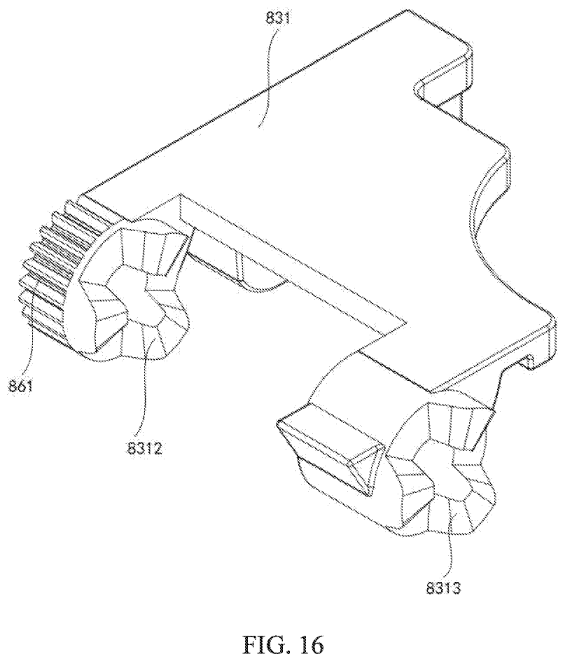

Referring to FIGS. 11 to 16, FIG. 11 is a diagram showing an overall structure of a second hinge according to one or more embodiments of the present application. FIG. 12 is a diagram showing detailed structure of a second hinge body of FIG. 11. FIG. 13 is an exploded view of the second hinge body of FIG. 12. FIG. 14 is a diagram showing detailed structure of a second body bracket of FIG. 13. FIG. 15 is a diagram showing detailed structure of a third support of FIG. 13. FIG. 16 is a diagram showing detailed structure of a third rotator of FIG. 13. The second hinge 32 includes a second support plate 70 and two second hinge bodies 80 positioned on opposite sides of the second support plate 70. The second support plate 70 includes a third sub-supporting plate 71 and a fourth sub-supporting plate 72, as shown in FIG. 11, where (a) in FIG. 11 is a schematic diagram showing structure of a front face of the second hinge 32, and (b) in FIG. 11 is a schematic diagram showing structure of a rear face of the second hinge 32. The front face of the second hinge 32 refers to the face of the second hinge 32 close to the flexible display panel body 10. The rear face of the second hinge 32 refers to the face of the second hinge 32 away from the flexible display panel body 10. The second hinge body 80 includes a second fixing bracket 81, a second supporting mechanism 82, a second rotating mechanism 83, a second linkage mechanism 86, and a second positioning mechanism 88.

The second fixing bracket 81 includes a second body bracket 810, a third bracket 811 and a fourth bracket 812, where the third bracket 811 is positioned between the second body bracket 810 and the fourth bracket 812 and fixedly connected to the second body bracket 810. The second supporting mechanism 82 includes a third support 821 and a fourth support 822 positioned on opposite sides of the second body bracket 810. The third support 821 is rotatably connected to one side of the second body bracket 810. A side of the third support 821 away from the second body bracket 810 is fixedly connected to the second middle frame 22, while the second middle frame 22 is also fixedly connected to the third sub-supporting plate 71. The fourth support 822 is rotatably connected to the other side of the second body bracket 810. A side of the fourth support 822 away from the second body bracket 810 is fixedly connected to the third middle frame 23, while the third middle frame 23 is also fixedly connected to the fourth sub-support plate 72.

Specifically, the third support 821 is provided with a third arc-shaped arm 8211 close to one side of the second body bracket 810. A third arc-shaped recess 8101 is provided on the one side of the second body bracket 810. The third arc-shaped arm 8211 is received in the third arc-shaped recess 8101 and slides in the third arc-shaped recess 8101. The fourth support 822 is provided with a fourth arc-shaped arm 8221 close to the other side of the second body bracket 810. The other side of the second body bracket 810 is provided with a fourth arc-shaped recess 8102. The fourth arc-shaped arm 8221 is received in the fourth arc-shaped recess 8102 and slides in the fourth arc-shaped recess 8102. For the specific structures of the third arc-shaped recess 8101 and the fourth arc-shaped recess 8102, one may refer to the described structure of the first arc-shaped recess 6101, and details are not described herein.

The second rotating mechanism 83 includes a third rotator 831 slidably connected to the third support 821 and a fourth rotator 832 slidably connected to the fourth support 822. Optionally, the third rotator 831 is slidably connected to the third support 821 by a fifth shaft 823, and the fourth rotator 832 is slidably connected to the fourth support 822 by a sixth shaft 824. One side of the third rotator 831 close to the third support 821 is provided with a first circular arc recess 8311. One side of the third support 821 close to the third rotator 831 is provided with a first projection 8212. A first circular hole 8213 is provided on the first projection 8212. The fifth shaft 823 passes through the first circular arc recess 8311 on the third rotator 831 and the first circular hole 8213 on the third support 821, so that the third rotator 831 and the third support 821 are slidably connected. In order to prevent the third support 821 from falling off the fifth shaft 823, the second hinge body 80 further includes a fifth fastener 8231 detachably connected to the fifth shaft 823. Accordingly, one side of the fourth rotator 832 close to the fourth support 822 is provided with a second circular arc recess 8321. One side of the fourth support 822 close to the fourth rotator 832 is provided with a second projection. The second projection is provided with a second circular hole. The sixth shaft 824 passes through the second circular arc recess 8321 on the fourth rotator 832 and the second circular hole on the fourth support 822, so that the fourth rotator 832 and the fourth support 822 are slidably connected. To prevent the fourth support 822 from falling off the sixth shaft 824, the second hinge body 80 further includes a sixth fastener 8241 detachably connected to the sixth shaft 824.

The second rotating mechanism 83 further includes a third rotating shaft 833 rotatably connected to the third bracket 811 and the fourth bracket 812, and a fourth rotating shaft 834 rotatably connected to the third bracket 811 and the fourth bracket 812. To prevent the fourth bracket 812 from falling off the third rotating shaft 833 and the fourth rotating shaft 834, the second hinge body 80 further includes a seventh fastener 8331 detachably connected to the third rotating shaft 833 and an eighth fastener 8341 detachably connected to the fourth rotating shaft 834.

The third rotator 831 is connected to the fourth rotator 832 through the second linkage mechanism 86, so that the third rotator 831 and the fourth rotator 832 rotate synchronously. The second linkage mechanism 86 includes a fourth linkage 861, a fifth linkage 862, and a sixth linkage 863. The fourth linkage 861 is fixedly connected to the third rotator 831. The sixth linkage 863 is fixedly connected to the fourth rotator 832. The fifth linkage 862 is rotatably connected to the third bracket 811. The fourth linkage 861 is synchronously connected to the sixth linkage 863 through the fifth linkage 862 so that the third rotator 831 and the fourth rotator 832 rotate synchronously.

One side of the third rotator 831 close to the third bracket 811 is provided with a third cam 8312. The third cam 8312 is sleeved on the third rotating shaft 833. One side of the fourth rotator 832 close to the third bracket 811 is provided with a fourth cam 8322. The fourth cam 8322 is sleeved on the fourth rotating shaft 834.

The second hinge 32 further includes a second positioning mechanism 88 including a second positioner 881, a third elastic element 8821, and a fourth elastic clement 8822. The second positioner 881 is sleeved on the third rotating shaft 833 and the fourth rotating shaft 834. One side of the second positioner 881 close to the third rotator 831 is provided with a third concave wheel 8811 matched with the third cam 8312. One side of the second positioner 881 close to the fourth rotator 832 is provided with a fourth concave wheel 8812 matched with the fourth cam 8322.

The third clastic clement 8821 is sleeved on the third rotating shaft 833. The fourth elastic element 8822 is sleeved on the fourth rotating shaft 834. Both the third clastic element 8821 and the fourth elastic element 8822 are positioned between the second positioner 881 and the fourth bracket 812. Both the third elastic element 8821 and the fourth clastic element 8822 are in an elastically deformed state.

Optionally, the fourth linkage 861 is integrally provided with the third cam 8312. The sixth linkage 863 is integrally provided with the fourth cam 8322. The fourth linkage 861 includes a fourth gear, the fifth linkage 862 includes a fifth gear, and the sixth linkage 863 includes two sixth gears meshing with each other. The two sixth gears are rotatably connected to the third bracket 811 and the second positioner 881. The fourth gear is sleeved on the third rotating shaft 833. The fifth gear is sleeved on the fourth rotating shaft 834. The fourth gear meshes with one of the two sixth gears, and the fifth gear meshes with the other of the two sixth gears.

Further, one side of the third rotator 831 close to the fourth bracket 812 is provided with a fifth cam 8313. The fifth cam 8313 is sleeved on the third rotating shaft 833. The third elastic element 8821 is positioned between the second positioner 881 and the fifth cam 8313. One side of the fourth rotator 832 close to the fourth bracket 812 is provided with a sixth cam 8323. The sixth cam 8323 is sleeved on the fourth rotating shaft 834. The fourth elastic element 8822 is positioned between the second positioner 881 and the sixth cam 8323.

The second positioning mechanism 88 further includes a third positioner 883, a fifth elastic element 8861, and a sixth elastic element 8862. The third positioner 883 is sleeved on the third rotating shaft 833 and the fourth rotating shaft 834. One side of the third positioner 883 close to the third rotator 831 is provided with a fifth concave wheel 8831 matched with the fifth cam 8313. One side of the third positioner 883 close to the fourth rotator 832 is provided with a sixth concave wheel 8832 matched with the sixth cam 8323.

The fifth elastic element 8861 is sleeved on the third rotating shaft 833. the sixth elastic element 8862 is sleeved on the fourth rotating shaft 834. Both the fifth elastic element 8861 and the sixth elastic element 8862 are positioned between the third positioner 883 and the fourth bracket 812. Both the fifth elastic element 8861 and the sixth elastic element 8862 are in an elastically deformed state. The second positioning mechanism 88 of the second hinge body 80 is provided with an additional set of positioners and elastic elements in comparison with the first positioning mechanism 65 of the first hinge body 60, so that the torque of the second hinge body 80 is increased. In this way, when the display panel 100 is closed, the first hinge body 60 is first closed, and then the second hinge body 80 is closed, so that the display panel 100 is folded in a preset folding order, thereby avoiding damage to the display panel 100 if it were not folded in the folding order and realizing a function of fool-proof folding of the display panel 100.

The effectiveness of fool-proof folding realized by increasing the torque of the second hinge 32 according to the embodiments of the present application will be illustrated by simulation.

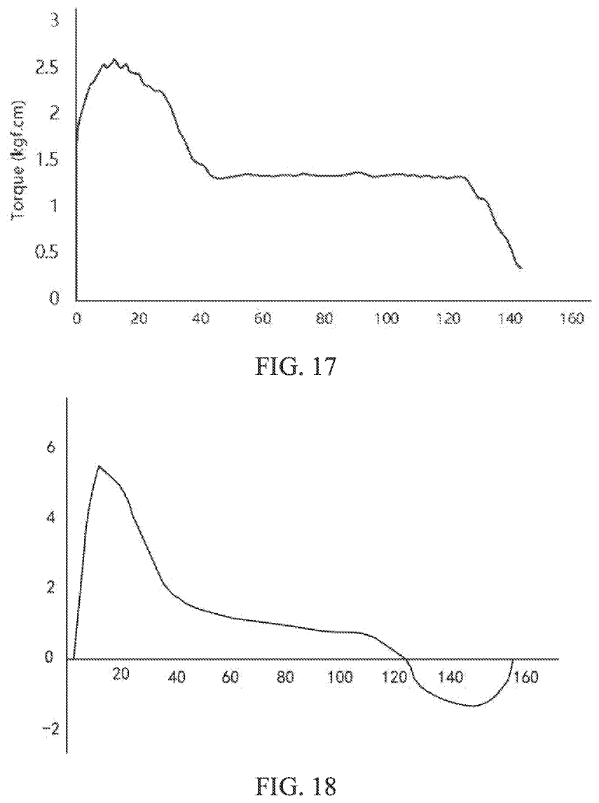

Referring to FIGS. 1-18, FIG. 17 is a torque simulation graph of a first hinge according to one or more embodiments of the present application. FIG. 18 is a torque simulation graph of a second hinge according to one or more embodiments of the present application. As shown in FIGS. 17 and 18, an abscissa indicates an angle at which the hinge is folded, an ordinate indicates a magnitude of the torque of the hinge. The curve indicates the magnitude of the torque corresponding to the change in the angle at which the hinge is folded. Comparison of FIG. 17 and FIG. 18 shows that, when the folding angle is about 20 degrees, torque values of the hinges are maximum, and a maximum torque value of the second hinge is much greater than the maximum torque value of the first hinge. In this way, when identical external forces are applied to close the display panel 100, the first hinge 31 is closed first due to the relatively small torque, and the second hinge 32 is closed later due to the relatively large torque, so that the display panel 100 can be folded in a preset folding order, thereby avoiding damage to the display panel 100 if it were not folded in the folding order and realizing the function of fool-proof folding of the display panel 100.

Based on the same inventive concept, one or more embodiments of the present application further provides an electronic device including a display panel 100 of one of the foregoing embodiments. The electronic device includes an electronic display product such as a mobile phone, a tablet, and a television.

It can be seen from the above embodiments that:

The present application provides a display panel and an electronic device, the display panel including at least three middle frames and at least two hinges, every two adjacent middle frames being rotationally connected, each of the hinges being connected to the two adjacent middle frames, and torques of any two adjacent hinges being different. According to the present application, torques of the two adjacent hinges of the display panel are different. When a display panel is to be folded, a hinge with a relatively small torque will be closed first, and a hinge with a relatively large torque will be closed later, so that the display panel can be folded according to a preset folding order, damage to the display panel caused if it were not folded according to the folding order is avoided. In this way, fool-proof folding of the display panel is realized, and the problem that the existing folding display device is vulnerable during folding is solved.

In the above-mentioned embodiments, the description of each embodiment has its own emphasis, and parts not described in detail in a certain embodiment may be referred to the related description of other embodiments.

The principles and embodiments of the present application are described herein using specific examples. The foregoing description of the embodiments is merely intended to assist in understanding the technical solution of the present application and the core concepts thereof. It will be appreciated by those of ordinary skill in the art that modifications may still be made to the technical solutions described in the foregoing embodiments, or equivalents may be made to some of the technical features therein. These modifications or substitutions do not depart the essence of the corresponding technical solutions from the scope of the technical solutions of the embodiments of the present application.

What is claimed is:

1. A display panel comprising:
at least three middle frames, every two adjacent said middle frames being rotatably connected; and
at least two hinges, each of said hinges being connected to two adjacent said middle frames;
wherein torques of any two adjacent hinges are different.

2. The display panel according to claim 1, wherein when the display panel is in a first state, the at least three middle frames are successively arranged in a first direction to form a flat surface, wherein any three adjacent middle frames are successively a first middle frame, a second middle frame and a third middle frame, the second middle frame is positioned between the first middle frame and the third middle frame, the first middle frame is rotatably connected to the second middle frame through a first hinge, the third middle frame is rotatably connected to the second middle frame through a second hinge, and the torque of the first hinge is less than the torque of the second hinge;
when the display panel is in a second state, the second middle frame, the first middle frame, and the third middle frame are arranged to overlap in a second direction, and the first middle frame is positioned between the second middle frame and the third middle frame.

3. The display panel according to claim 2, wherein in the first direction, a length of the first middle frame is smaller than a length of the second middle frame, and a length of the second middle frame is smaller than a length of the third middle frame.

4. The display panel according to claim 3, wherein when the display panel is in the first state, a thickness of the first middle frame gradually increases in the first direction, a thickness of the third middle frame gradually decreases in the first direction, and a thickness of a side of the first middle frame close to the first hinge is larger than a thickness of a side of the first middle frame away from the first hinge.

5. The display panel according to claim 2, wherein one of the first hinge and the second hinge is a flex hinge and the other is a U-shaped hinge.

6. The display panel according to claim 2, wherein the first hinge comprises:
a first fixing bracket, comprising a first body bracket;
a first supporting mechanism, comprising a first support and a second support positioned at opposite sides of the first body bracket, the first support being rotatably connected to one side of the first body bracket, and the second support being rotatably connected to the other side of the first body bracket;
a first rotating mechanism, comprising a first rotator, a second rotator, a first connector, and a second connector, one end of the first rotator being rotatably connected to one side of the first support away from the first body bracket, the other side of the first rotator being fixedly connected to the first middle frame, one end of the second rotator being rotatably connected to one side of the second support away from the first body bracket, the other side of the second rotator being fixedly connected to the second middle frame, one end of the first connector being slidably connected to the first rotator, and one end of the second connector being slidably connected to the second rotator; and
a first linkage mechanism, wherein the other end of the first connector is fixedly connected to one end of the first linkage mechanism, and the other end of the second connector is fixedly connected to the other end of the first linkage mechanism so that the first rotator and the second rotator rotate synchronously.

7. The display panel according to claim 6, wherein the first rotating mechanism further comprises a first rotating shaft and a second rotating shaft, the first rotating shaft being fixedly connected to the first connector and fixedly connected to the end of the first linkage mechanism; the second rotating shaft being fixedly connected to the second connector and fixedly connected to the other end of the first linkage mechanism.

8. The display panel according to claim 7, wherein the first fixing bracket further comprises a first bracket and a second bracket, the first bracket being positioned between the second bracket and the first body bracket, the first linkage mechanism being provided between the first bracket and the first body bracket, wherein the first rotating shaft and the second rotating shaft are rotatably connected to the first body bracket, and the first bracket and the second bracket are sleeved on the first rotating shaft and the second rotating shaft.

9. The display panel according to claim 8, wherein the first linkage mechanism comprises a first linkage connected to the first rotating shaft, a second linkage connected to the second rotating shaft, and a third linkage, the first linkage being synchronously connected to the second linkage through the third linkage so that the first rotating shaft and the second rotating shaft rotate synchronously.

10. The display panel according to claim 9, wherein the other end of the first connector is provided with a first cam on a side away from the first linkage, and the other end of the second connector is provided with a second cam on a side away from the second linkage; and
the first hinge further comprises a first positioning mechanism, wherein the first positioning mechanism comprises a first positioner sleeved on the first rotating shaft and the second rotating shaft, a first concave wheel matched with the first cam is arranged on one side of the first positioner close to the first connector, and a second concave wheel matched with the second cam is arranged on one side of the first positioner close to the second connector.

11. The display panel according to claim 10, wherein the first positioning mechanism further comprises a first elastic element and a second elastic element, wherein the first elastic element is sleeved on the first rotating shaft, the second elastic element is sleeved on the second rotating shaft, both the first elastic element and the second elastic element are positioned between the first positioner and the second bracket, and both the first elastic element and the second elastic element are in an elastically deformed state.

12. The display panel according to claim 2, wherein the second hinge comprises:
a second fixing bracket, comprising a second body bracket;
a second supporting mechanism, comprising a third support and a fourth support positioned on opposite sides of the second body bracket, the third support being rotatably connected to one side of the second body bracket, one side of the third support away from the second body bracket being fixedly connected to the second middle frame, the fourth support being rotatably connected to the other side of the second body bracket, and one side of the fourth support away from the second body bracket being fixedly connected to the third middle frame;
a second rotating mechanism, comprising a third rotator slidably connected to the third support and a fourth rotator slidably connected to the fourth support;
a second linkage mechanism, through which the third rotator is connected to the fourth rotator so that the third rotator and the fourth rotator rotate synchronously.

13. The display panel according to claim 12, wherein the second fixing bracket further comprises a third bracket and a fourth bracket, the third bracket is positioned between the fourth bracket and the second body bracket, and the second linkage mechanism is disposed between the third bracket and the fourth bracket; and
the second linkage mechanism comprises a fourth linkage, a fifth linkage and a sixth linkage, wherein the fourth linkage is fixedly connected to the third rotator, the sixth linkage is fixedly connected to the fourth rotator, the fifth linkage is rotatably connected to the third bracket, and the fourth linkage is synchronously connected to the sixth linkage by the fifth linkage so that the third rotator and the fourth rotator rotate synchronously.

14. The display panel according to claim 13, wherein the second rotating mechanism further comprises a third rotating shaft rotatably connected to the third bracket and the fourth bracket, and a fourth rotating shaft rotatably connected to the third bracket and the fourth bracket;
wherein the third rotator is provided with a third cam on one side close to the third bracket, the third cam is sleeved on the third rotating shaft, the fourth rotator is provided with a fourth cam on one side close to the third bracket, and the fourth cam is sleeved on the fourth rotating shaft;
the second hinge further comprises a second positioning mechanism, wherein the second positioning mechanism comprises a second positioner, a third elastic element and a fourth elastic element, the second positioner is sleeved on the third rotating shaft and the fourth rotating shaft, a third concave wheel matched with the third cam is arranged on one side of the second positioner close to the third rotator, and a fourth concave wheel matched with the fourth cam is arranged on one side of the second positioner close to the fourth rotator; and
the third elastic element is sleeved on the third rotating shaft, the fourth elastic element is sleeved on the fourth rotating shaft, both the third elastic element and the fourth elastic element are positioned between the second positioner and the fourth bracket, and both the third elastic element and the fourth elastic element are in an elastically deformed state.

15. The display panel according to claim 14, wherein the fourth linkage is integrally provided with the third cam, and the sixth linkage is integrally provided with the fourth cam.

16. The display panel according to claim 14, wherein the third rotator is provided with a fifth cam on a side close to the fourth bracket, the fifth cam is sleeved on the third rotating shaft, the third elastic element is positioned between the second positioner and the fifth cam, the fourth rotator is provided with a sixth cam on a side close to the fourth bracket, the sixth cam is sleeved on the fourth rotating shaft, and the fourth elastic element is positioned between the second positioner and the sixth cam;
the second positioning mechanism further comprises a third positioner, a fifth elastic element and a sixth elastic element, the third positioner is sleeved on the third rotating shaft and the fourth rotating shaft, a fifth concave wheel matched with the fifth cam is arranged on one side of the third positioner close to the third rotator, and a sixth concave wheel matched with the sixth cam is arranged on one side of the third positioner close to the fourth rotator; and
the fifth elastic element is sleeved on the third rotating shaft, the sixth elastic element is sleeved on the fourth rotating shaft, both the fifth elastic element and the sixth elastic element are positioned between the third positioner and the fourth bracket, and both the fifth elastic element and the sixth elastic element are in an elastically deformed state.

17. An electronic device comprising a display panel comprising:
at least three middle frames, every two adjacent said middle frames being rotatably connected; and
at least two hinges, each of said hinges being connected to two adjacent said middle frames:
wherein torques of any two adjacent hinges are different.

18. The electronic device according to claim 17, wherein when the display panel is in a first state, the at least three middle frames are successively arranged in a first direction to form a flat surface, wherein any three adjacent middle frames are successively a first middle frame, a second middle frame and a third middle frame, the second middle frame is positioned between the first middle frame and the third middle frame, the first middle frame is rotatably connected to the second middle frame through a first hinge, the third middle frame is rotatably connected to the second middle frame through a second hinge, and the torque of the first hinge is less than the torque of the second hinge;
when the display panel is in a second state, the second middle frame, the first middle frame, and the third middle frame are arranged to overlap in a second direction, and the first middle frame is positioned between the second middle frame and the third middle frame.

19. The electronic device according to claim 18, wherein in the first direction, a length of the first middle frame is smaller than a length of the second middle frame, and a length of the second middle frame is smaller than a length of the third middle frame.

20. The electronic device according to claim 19, wherein when the display panel is in the first state, a thickness of the first middle frame gradually increases in the first direction, a thickness of the third middle frame gradually decreases in the first direction, and a thickness of a side of the first middle frame close to the first hinge is larger than a thickness of a side of the first middle frame away from the first hinge.
